(19) United States
(12) Patent Application Publication
(10) Pub. No.: US 2025/0359031 A1
(43) Pub. Date: Nov. 20, 2025

(54) MANAGING CONNECTION STRUCTURES IN SEMICONDUCTOR DEVICES

(71) Applicant: Yangtze Memory Technologies Co., Ltd., Wuhan (CN)

(72) Inventors: Yuhuan ZHENG, Wuhan (CN); Yonggang YANG, Wuhan (CN); Hongxia MA, Wuhan (CN); Zhanhai XIAO, Wuhan (CN); Junzheng ZHANG, Wuhan (CN)

(21) Appl. No.: 18/782,996

(22) Filed: Jul. 24, 2024

(30) Foreign Application Priority Data
May 20, 2024 (CN) 202410627887.0

(51) Int. Cl. H10B 12/00

(52) U.S. Cl. CPC H10B 12/482; H10B 12/0335; H10B 12/315

(57) ABSTRACT

Systems, devices, and methods for managing connection structures in a semiconductor device are provided. In one aspect, a semiconductor device includes a transistor. The transistor includes a semiconductor body having a first end and a second end that are doped. A connection structure includes a first end and a second end. The first end of the connection structure is a seamless conductive portion including a conductive material without air gap. The first end of the connection structure is in contact with the first end of the semiconductor body.

### CROSS-REFERENCE TO RELATED APPLICATIONS

This application claims priority to Chinese Patent Application No. 202410627887.0, filed on May 20, 2024, which is hereby incorporated by reference in its entirety.

### TECHNICAL FIELD

The present disclosure relates to semiconductor devices and fabrication processes for semiconductor devices.

### BACKGROUND

Semiconductor memory devices may be classified into non-volatile memory devices, such as flash memory devices, and volatile memory devices, such as dynamic random-access memory (DRAM). The semiconductor memory devices can have different structures with different densities of memory cells and lines on a chip. A memory device normally includes a memory array of memory cells and control circuitries. The control circuitries can facilitate operations of the memory array.

During semiconductor device fabrication, air gaps can be formed whether intentionally or unintentionally. Air gaps can be advantageous in some structures, but detrimental in others. For example, on one hand, the relatively small dielectric constant of air in the air gaps may provide good insulation. On the other hand, air gaps may cause electrical shorts between adjacent conductors or affect the integrity of stored data.

### SUMMARY

The present disclosure describes methods, devices, systems and techniques for managing connection structures in three-dimensional (3D) semiconductor devices.

One aspect of the present disclosure features a semiconductor device, including a transistor. The transistor includes a semiconductor body having a first end and a second end that are doped. A connection structure includes a first end and a second end. The first end of the connection structure is a seamless conductive portion including a conductive material without air gap. The first end of the connection structure is in contact with the first end of the semiconductor body.

In some implementations, the conductive material includes germanium silicon (GeSi).

In some implementations, the conductive material includes a N type dopant or a P type dopant.

In some implementations, the connection structure includes a second conductive portion on the seamless conductive portion.

In some implementations, the second conductive portion includes a silicide material having silicon (Si) and at least one of cobalt (Co), nickel (Ni) or tungsten (W).

In some implementations, the silicide material further includes germanium (Ge).

In some implementations, the second conductive portion includes a tungsten (W) layer and a titanium nitride (TiN) layer.

In some implementations, the semiconductor body extends along a direction. The connection structure includes a third conductive portion between the seamless conductive portion and the second conductive portion. The third conductive portion includes a polysilicon with an air gap extending along the direction.

In some implementations, the semiconductor device includes a capacitor having a first electrode. The second end of the connection structure is coupled to the first electrode of the capacitor.

In some implementations, the semiconductor device includes a bit line. The second end of the connection structure is coupled to the bit line.

Another aspect of the present disclosure features a method including: forming a transistor including a semiconductor body on a substrate. A dielectric layer is deposited on the semiconductor body. An opening is formed extending through the dielectric layer to expose the semiconductor body. A seamless conductive portion is formed inside the opening. The seamless conductive portion includes a conductive material without air gap.

In some implementations, forming the seamless conductive portion inside the opening includes growing the conductive material from a bottom of the opening towards a top of the opening.

In some implementations, the conductive material includes germanium silicon (GeSi).

In some implementations, the conductive material is grown from the bottom of the opening towards the top of the opening using epitaxial growth or low-pressure chemical vapor deposition (LPCVD).

In some implementations, the method includes depositing polysilicon on the seamless conductive portion inside the opening.

In some implementations, the method includes depositing a first conductive layer on the polysilicon and annealing the first conductive layer such that the first conductive layer reacts with the polysilicon to form a first composite conductive material.

In some implementations, the method includes depositing a conductive layer on the seamless conductive portion and annealing the conductive layer such that the conductive layer reacts with the conductive material in the seamless conductive portion to form a composite conductive material.

In some implementations, the method includes depositing a titanium nitride (TiN) layer and a tungsten (W) layer on the first composite conductive material.

In some implementations, the method includes depositing a titanium nitride (TiN) layer and a tungsten (W) layer on the seamless conductive portion.

Another aspect of the present disclosure features a system including: a memory device configured to store data and a memory controller coupled to the memory device and configured to operate the memory device. The memory device includes a transistor and a connection structure. The transistor includes a semiconductor body having a first end and a second end that are doped. The connection structure includes a first end and a second end. The first end of the connection structure is a seamless conductive portion including a conductive material without air gap. The first end of the connection structure is in contact with the first end of the semiconductor body.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a cross-sectional view of an example 3D semiconductor device.

FIG. 2 illustrates a cross-section view of an example connection structure.

FIGS. 3A-3D illustrates cross-section views of an example connection structure at various stages of a fabrication process.

FIGS. 4A-4E illustrates cross-section views of an example connection structure at various stages of a fabrication process.

FIGS. 5A-5C illustrates cross-section views of an example connection structure at various stages of a fabrication process.

FIG. 6 illustrates an example process to form an example semiconductor device.

FIG. 7 illustrates a block diagram of a system having one or more semiconductor device.

It is to be understood that the various exemplary implementations shown in the figures are merely illustrative representations and are not necessarily drawn to scale.

### DETAILED DESCRIPTION

Implementations of the present disclosure provides a semiconductor device and a method to form such semiconductor device. In some implementations, the semiconductor device includes a transistor and a connection structure. The transistor includes a semiconductor body having a first end and a second end that are doped. The connection structure includes a first end and a second end. The first end of the connection structure is a seamless conductive portion including a conductive material without air gap. The first end of the connection structure is in contact with the first end of the semiconductor body.

Implementations of the present disclosure can provide one or more of the following technical advantages and/or benefits. First, a connection structure can be formed with at least one seamless conductive material without air gaps. The absence of air gaps or seams can reduce the likelihood of foreign conductive material contamination through such air gaps or seams during subsequent manufacturing process. For example, the connection structure can be utilized to couple a first electrode of a capacitor and an end of a transistor. If the connection structure includes unwanted air gaps or seams, during subsequent manufacturing process, foreign conductive materials, e.g., the first electrode, may flow through the air gaps and contaminate the transistor. A seamless conductive material in the connection structure can thus reduce the risk of contamination. Further, the seamless conductive material can also provide better electrical coupling between different components in a memory array, e.g., the coupling between the transistor and the capacitor, or the coupling between the transistor and a bit line. When the connection structures are seamless, there can be less impedance and resistance to the flow of electrical signals, resulting in improved electrical performance and reliability of the memory cells.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

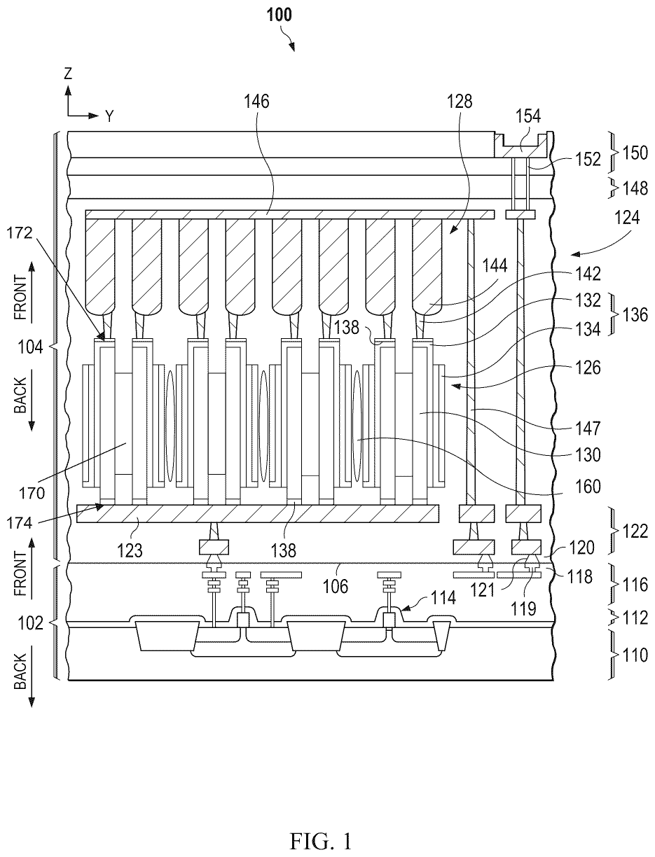

FIG. 1 illustrates a side view of a cross-section of an example 3D semiconductor device 100. The 3D semiconductor device 100 can be a 3D dynamic random-access memory (DRAM). It is understood that FIG. 1 is for illustrative purposes only and may not necessarily reflect the actual device structure (e.g., interconnections) in practice. In some implementations, the 3D semiconductor device 100 is a bonded chip including a first semiconductor structure 102 and a second semiconductor structure 104 stacked over the first semiconductor structure 102. The first and second semiconductor structures 102 and 104 can be jointed at bonding interface 106 therebetween.

As shown in FIG. 1, the first semiconductor structure 102 can include a substrate 110, which can include silicon (e.g., single crystalline silicon, c-Si), SiGe, GaAs, Ge, SOI, or any other suitable materials. The first semiconductor structure 102 can include peripheral circuits 112 on and/or in the substrate 110. In some implementations, the peripheral circuits 112 include a plurality of transistors 114 (e.g., planar transistors and/or 3D transistors). Trench isolations (e.g., shallow trench isolations (STIs)) and doped regions (e.g., wells, sources, and drains of transistors 114) can be formed on or in the substrate 110 as well. In some examples, the peripheral circuits 112 are formed using complementary metal-oxide-semiconductor (CMOS) technology, and the first semiconductor structure 102 can be also formed on a semiconductor die that can be referred to as a control die or a CMOS die 102.

In some implementations, the first semiconductor structure 102 further includes an interconnect layer 116 above the peripheral circuits 112 to transfer electrical signals to and from the peripheral circuits 112. The interconnect layer 116 can include a plurality of interconnects (also referred to herein as “contacts”), including lateral interconnect lines and VIA contacts. The interconnect layer 116 can further include one or more interlay dielectric (ILD) layers in which the interconnect lines and via contacts can form. That is, the interconnect layer 116 can include interconnect lines and via contacts in multiple ILD layers. In some implementations, peripheral circuits 112 are coupled to one another through the interconnects in the interconnect layer 116. The interconnects in interconnect layer 116 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 1, the first semiconductor structure 102 has a front side and a back side, and the first semiconductor structure 102 can further include a bonding layer 118 at the back side at the bonding interface 106 and above the interconnect layer 116 and the peripheral circuits 112. The bonding layer 118 can include a plurality of bonding contacts 119 and dielectrics electrically isolating the bonding contacts 119. The bonding contacts 119 can include conductive materials, such as Cu. The remaining area of the bonding layer 118 can be formed with dielectric materials, such as silicon oxide. The bonding contacts 119 and surrounding dielectrics in the bonding layer 118 can be used for hybrid bonding. Similarly, as shown in FIG. 1, the second semiconductor structure 104 can also include a bonding layer 120 at the bonding interface 106 and above the bonding layer 118 of the first semiconductor structure 102. The bonding layer 120 can include a plurality of bonding contacts 121 and dielectrics electrically isolating the bonding contacts 121. The bonding contacts 121 can include conductive materials, such as Cu. The remaining area of the bonding layer 120 can be formed with dielectric materials, such as silicon oxide. The bonding contacts 121 and surrounding dielectrics in the bonding layer 120 can be used for hybrid bonding. The bonding contacts 121 can be in contact with the bonding contacts 119 at the bonding interface 106. In some implementations, the bonding layer 120 includes a dielectric layer opposing memory cells (e.g., DRAM cells) 124 with a bit line 123 positioned between the dielectric layer and the memory cells 124, as shown in FIG. 1. The dielectric layer can include the bonding interface 106 having the bonding contacts 121.

The second semiconductor structure 104 can be bonded on top of the first semiconductor structure 102 in a face-to-face manner at the bonding interface 106. In some implementations, the bonding interface 106 is disposed between the bonding layers 120 and 118 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, the bonding interface 106 is the place at which bonding layers 120 and 118 are met and bonded. In some examples, the bonding interface 106 can be a layer with a certain thickness that includes the top surface of the bonding layer 118 of the first semiconductor structure 102 and the bottom surface of the bonding layer 120 of the second semiconductor structure 104.

In some implementations, the second semiconductor structure 104 further includes an interconnect layer 122 including bit lines 123 above the bonding layer 120 to transfer electrical signals. The interconnect layer 122 can include a plurality of interconnects, such as mid end of line (MEOL) interconnects and back end of line (BEOL) interconnects. In some implementations, the interconnects in interconnect layer 122 also include local interconnects, such as the bit lines 123 and word line contacts (not shown). The interconnect layer 122 can further include one or more ILD layers in which the interconnect lines and via contacts can form. The interconnects in the interconnect layer 122 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, the peripheral circuits 112 include a word line driver/row decoder coupled to the word line contacts in the interconnect layer 122 through the bonding contacts 121 and 119 in the bonding layers 120 and 118 and the interconnect layer 116. In some implementations, the peripheral circuits 112 include a bit line driver/column decoder coupled to the bit lines 123 and bit line contacts in the interconnect layer 122 through the bonding contacts 121 and 119 in the bonding layers 120 and 118 and the interconnect layer 116. In some implementations, the bit line 123 is a metal bit line, as opposed to semiconductor bit lines (e.g., doped silicon bit lines). For example, the bit line 123 may include W, Co, Cu, Al, or any other suitable metals having higher conductivities than doped silicon. In some implementations, the bit line contact is an ohmic contact as opposed to a Schottky contact.

In some implementations, the bit line 123 is made of a composite conductive material that can be based on a metallic material (e.g., W, Co, Cu, Al) and a semiconductor material (e.g., Si). For example, the composite conductive material can include metal silicide, e.g., such as WSi, CoSi, CuSi, AlSi, or any other suitable metal silicides having higher conductivities than doped silicon.

In some implementations, the second semiconductor structure 104 includes a DRAM device in which memory cells are provided in the form of an array of DRAM cells 124 above the interconnect layer 122 and the bonding layer 120. That is, the interconnect layer 122 including the bit lines 123 can be disposed between bonding layer 120 and array of DRAM cells 124. A bit line 123 in the interconnect layer 122 can be coupled to a string of DRAM cells 124. In some implementations, the second semiconductor structure 104 is formed on a semiconductor die and can be referred to as array die 104.

In some implementations, a semiconductor device can include multiple array dies (e.g., the array die 104) and a CMOS die (e.g., the CMOS die 102). The multiple array dies and the CMOS die can be stacked and bonded together. The CMOS die can be respectively coupled to each of the multiple array dies, and can respectively drive each of the multiple array dies to operate in the similar manner as the semiconductor device. The semiconductor device can be any suitable device. In some examples, the semiconductor device includes at least a first wafer and a second wafer bonded face to face. The array die can be disposed with other array dies on the first wafer, and the CMOS die can be disposed with other CMOS dies on the second wafer. The first wafer and the second wafer can be bonded together, thus the array dies on the first wafer can be bonded with corresponding CMOS dies on the second wafer. In some examples, the semiconductor device is a chip with at least the array die and the CMOS die bonded together. In an example, the chip is diced from wafers that are bonded together. In another example, the semiconductor device is a semiconductor package that includes one or more semiconductor chips assembled on a package substrate.

Each DRAM cell 124 can include a vertical transistor 126 and a capacitor 128 coupled to the vertical transistor 126. DRAM cell 124 can be a 1T1C cell consisting of one transistor and one capacitor. It is understood that DRAM cell 124 may be of any suitable configurations, such as 2T1C cell, 3T1C cell, etc. The vertical transistor 126 can be a MOSFET used to switch a respective DRAM cell 124. In some implementations, the vertical transistor 126 includes a semiconductor body 130 (the active region in which a channel can form) extending vertically (in the z-direction), and a gate structure 136 in contact with one side of semiconductor body 130. In a single-gate vertical transistor, the semiconductor body 130 can have a cuboid shape or a cylinder shape, and the gate structure 136 can abut a single side of semiconductor body 130 in a plane view, e.g., as shown in FIG. 1. In some implementations, the gate structure 136 includes a gate electrode 134 and a gate dielectric 132 laterally between the gate electrode 134 and the semiconductor body 130 in a bit line direction (e.g., in the Y direction). In some implementations, the gate dielectric 132 abuts one side of the semiconductor body 130, and the gate electrode 134 abuts the gate dielectric 132. In some implementations, the vertical transistor 126 has a structure including two or more gates, e.g., a two-gates structure, a three-gates structure, or a gate all around (GAA) structure.

As shown in FIG. 1, in some implementations, the semiconductor body 130 has two ends (the first end 172 and the lower end 172 in FIG. 1) in the vertical direction (the z-direction), and at least one end (e.g., the lower end) extends beyond gate dielectric 132 in the vertical direction (the z-direction) into the ILD layers. In some implementations, the first end 172 of the semiconductor body 130 is coupled to or in contact with the connection structure 142, while the second end 174 of the semiconductor body 130 is coupled to the bit lines 123. In some implementations, the two ends of the semiconductor body 130 are doped. The dopants can include N+ type dopants (e.g., Phosphorus (P) or Arsenic (As)) or P-type dopants (e.g., Boron (B) or Gallium (Ga)) at a desired doping level. In some implementations, the concentration range of dopants at the two ends of the semiconductor body 130 falls within 1E14 to 1E16 dopant atoms per cubic centimeter. In some implementations, the dopant level of the semiconductor body 130 is lower than the dopant level of the source or drain 138 of the transistor 126.

In some implementations, an end (e.g., the upper end) of the semiconductor body 130 is flush with the respective end (e.g., the upper end) of the gate dielectric 132. In some implementations, both ends (the upper end and lower end) of the semiconductor body 130 extend beyond the gate electrode 134, respectively, in the vertical direction (the z-direction) into ILD layers. That is, the semiconductor body 130 can have a larger vertical dimension (e.g., the depth) than that of the gate electrode 134 (e.g., in the z-direction), and neither the upper end nor the lower end of semiconductor body 130 is flush with the respective end of the gate electrode 134. Thus, short circuits between the bit lines 123 and the word lines/gate electrodes 134 or between the word lines/gate electrodes 134 and the capacitors 128 can be avoided. The vertical transistor 126 can further include a source and a drain (both referred to as 138 as their locations may be interchangeable) disposed at the two ends (the upper end and lower end) of the semiconductor body 130, respectively, in the vertical direction (the z-direction). In some implementations, one of the source and drain 138 (e.g., at the upper end in FIG. 1) is coupled to the capacitor 128, and the other one of source and drain 138 (e.g., at the lower end in FIG. 1) is coupled to the bit line 123. That is, the vertical transistor 126 can have a first terminal in the positive z-direction and a second terminal opposite the first terminal in the negative z-direction, as shown in FIG. 1.

In some implementations, the semiconductor body 130 includes semiconductor materials, such as single crystalline silicon, polysilicon, amorphous silicon, Ge, any other semiconductor materials, or any combinations thereof. In one example, semiconductor body 130 may include single crystalline silicon. Source and drain 138 can be doped with N+ type dopants (e.g., Phosphorus (P) or Arsenic (As)) or P-type dopants (e.g., Boron (B) or Gallium (Ga)) at a desired doping level. In some implementations, a silicide layer, such as a metal silicide layer, is formed between source/drain 138 of the vertical transistor 126 and the bit line 123 as the bit line contact or between source/drain 138 of the vertical transistor 126 and the first electrode of the capacitor 128 as connection structure 142 to reduce the contact resistance. In some implementations, gate dielectric 132 includes dielectric materials, such as silicon oxide, silicon nitride, or high-k dielectrics including, but not limited to, Al2O3, HfO2, Ta2O5, ZrO2, TiO2, or any combination thereof. In some implementations, gate electrode 134 includes a conductive material including, but not limited to W, Co, Cu, Al, TiN, TaN, polysilicon, silicide, or any combination thereof. In some implementations, the gate electrode 134 includes multiple conductive layers, such as a W layer over a TiN layer. In one example, the gate structure 136 may be a “gate oxide/gate poly” gate in which the gate dielectric 132 includes silicon oxide and gate electrode 134 includes doped polysilicon. In another example, gate structure 136 may be an HKMG in which gate dielectric 132 includes a high-k dielectric and gate electrode 134 includes a metal.

As described above, since the gate electrode 134 may be part of a word line or extend in the word line direction (e.g., the X direction) as a word line, the second semiconductor structure 104 of the 3D semiconductor device 100 can also include a plurality of word lines each extending in the word line direction. Each word line 134 can be coupled to a row of DRAM cells 124. That is, the bit line 123 and the word line 134 can extend in two perpendicular lateral directions, and the semiconductor body 130 of the vertical transistor 126 can extend in the vertical direction perpendicular to the two lateral directions in which the bit line 123 and the word line 134 extend. Word lines 134 are in contact with word line contacts (not shown). In some implementations, the word lines 134 include conductive materials including, but not limited to W, Co, Cu, Al, TiN, TaN, polysilicon, silicides, or any combination thereof. In some implementations, the word line 134 includes multiple conductive layers, such as a W layer over a TiN layer, as shown in FIG. 1.

In some implementations, as shown in FIG. 1, the vertical transistor 126 extends vertically through and contacts the word lines 134, and the source or drain 138 of vertical transistor 126 at the lower end thereof is in contact with the bit line 123 (or bit line contact if any). Accordingly, the word lines 134 and the bit lines 123 can be disposed in different planes in the vertical direction due to the vertical arrangement of vertical transistor 126, which simplifies the routing of the word lines 134 and the bit lines 123. In some implementations, the bit lines 123 are disposed vertically between the bonding layer 120 and the word lines 134, and the word lines 134 are disposed vertically between the bit lines 123 and the capacitors 128. The word lines 134 can be coupled to the peripheral circuits 112 in the first semiconductor structure 102 through word line contacts (not shown) in the interconnect layer 122, the bonding contacts 121 and 119 in the bonding layers 120 and 118, and the interconnects in the interconnect layer 116. Similarly, the bit lines 123 in the interconnect layer 122 can be coupled to the peripheral circuits 112 in the first semiconductor structure 102 through the bonding contacts 121 and 119 in the bonding layers 120 and 118 and the interconnects in the interconnect layer 116.

In some implementations, the vertical transistors 126 can be arranged in a mirror-symmetric manner to increase the density of DRAM cells 124 in the bit line direction (the Y direction). As shown in FIG. 1, two adjacent vertical transistors 126 in the bit line direction are mirror-symmetric to one another with respect to a trench isolation 160. That is, the second semiconductor structure 104 can include a plurality of trench isolations 160 each extending in the word line direction (the X direction) in parallel with word lines 134 and disposed between vertical gates 134 of two adjacent rows of the vertical transistors 126. In some implementations, the rows of vertical transistors 126 separated by the trench isolation 160 are mirror-symmetric to one another with respect to the trench isolation 160. The trench isolation 160 can be formed with dielectric materials including, but not limited to, silicon oxide, silicon nitride, silicon oxynitride, low-k dielectrics, or any combination thereof. It is understood that the trench isolation 160 may include an air gap each disposed laterally between adjacent vertical gates 134. Air gaps may be formed due to the relatively small pitches of vertical transistors 126 in the bit line direction (e.g., the Y direction). On the other hand, the relatively large dielectric constant of air in air gaps (e.g., about 4 times of the dielectric constant of silicon oxide) can improve the insulation effect between vertical transistors 126 (and rows of DRAM cells 124) compared with some dielectrics (e.g., silicon oxide). Similarly, in some implementations, air gaps are formed laterally between word lines/gate electrodes 134 in the bit line direction as well, depending on the pitches of word lines/gate electrodes 134 in the bit line direction.

In some implementations, instead of the trench isolation 160 having the air gap being disposed between adjacent vertical gates 134 of two adjacent rows of the vertical transistors 126, a shielding conductive structure 170 (e.g., including metal such as W) is disposed between adjacent semiconductor bodies 130 of two adjacent rows of vertical transistors 126. The shielding conductive structure 170 can be in contact with at least one of the adjacent semiconductor bodies 130 and can be coupled to a low voltage (e.g., a fixed negative voltage), which can reduce charge build-up in the memory cells 124, thereby mitigating the floating body effect in the memory cells 124. Moreover, by applying a fixed low voltage on the shielding conductive structure 170 between the memory cells 124, a threshold voltage of the memory cells 124 can be conveniently adjusted, which can reduce the overall manufacturing complexity and cost, and improve reliability of the memory cells 124. Further, the conductive structure 170 can be coupled out from a same side as word lines or a different side from the word lines. For example, the shielding conductive structure 170 can be coupled out from the back side of the second semiconductor structure 104. The shielding conductive structure 170 can be also referred as shielding conductive material. The trench isolation having such shielding conductive structure 170 can be referred as trench isolation (TISO) in this disclosure.

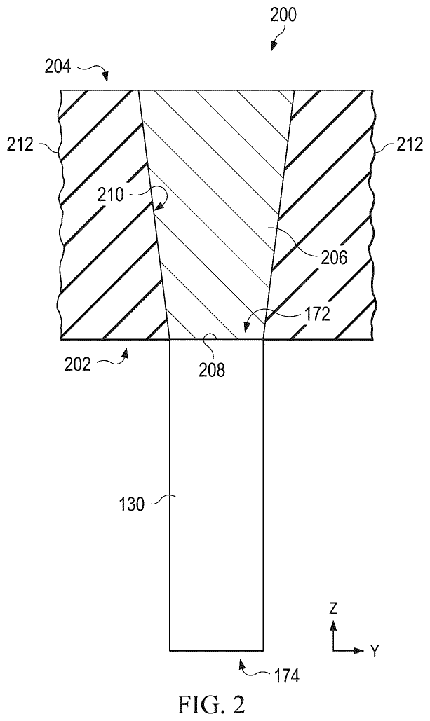

As shown in FIG. 1, in some implementations, a capacitor 128 includes a first electrode 144 above and coupled to the source or drain 138 of vertical transistor 126, e.g., the upper end of the semiconductor body 130, via a connection structure 142. In some implementations, the connection structure 142 is an ohmic contact, such as a metal silicide contact, as opposed to a Schottky contact. For example, the connection structure 142 can include doped silicon. In some cases, the doped silicon can include unwanted air gaps or seams extending along the Z direction. During subsequent manufacturing process, foreign conductive materials may flow through the air gaps and contaminate the transistor 126. In some implementations, the connection structure 142 includes a seamless material, e.g., germanium silicon (GeSi), as describe with further details below in FIGS. 2-5C. GeSi can be epitaxially grown without air gaps, thereby reducing the likelihood of foreign conductive material contamination through such gaps or seams.

In some implementations, the connection structure 142 is located between the second end 174 of the semiconductor body 130 and bit lines 123. A first end of the connection structure 142 can be coupled to the semiconductor body 130, and a second end of the connection structure 142 can be coupled to the bit line.

The capacitor 128 can also include a capacitor dielectric above and in contact with the first electrode 144, and a second electrode above and in contact with the capacitor dielectric. That is, the capacitor 128 can be a vertical capacitor in which the electrodes and capacitor dielectric are stacked vertically (in the z-direction), and the capacitor dielectric can be sandwiched between the electrodes. In some implementations, each first electrode is coupled to source or drain 138 of a respective vertical transistor 126 in the same DRAM cell, while all second electrodes are coupled to a common plate 146 coupled to the ground, e.g., a common ground. The capacitor 128 can have a first end in the negative z-direction and a second end opposite the first end in the positive z-direction, as shown in FIG. 1. In some implementations, the first end of the capacitor 128 is coupled to the first terminal of the vertical transistor 126 via an ohmic contact (e.g., the connection structure 142 made of a metal silicide material). As shown in FIG. 1, the second semiconductor structure 104 can further include a capacitor contact 147 (e.g., a conductor) in contact with a common plate 146 for coupling the capacitors 128 to the peripheral circuits 112 or to the ground directly. In some implementations, the capacitor contact 147 (e.g., a conductor) extends in the z-direction from the dielectric layer of the bonding layer 120 to couple to the second end of the capacitor 128 via the common plate 146, as shown in FIG. 1. In some implementation, the ILD layer in which the capacitors 128 are formed has the same dielectric material as the two ILD layers into which the semiconductor body 130 extends, such as silicon oxide.

It is understood that the structure and configuration of a capacitor 128 are not limited to the example in FIG. 1 and may include any suitable structure and configuration, such as a planar capacitor, a stack capacitor, a multi-fins capacitor, a cylinder capacitor, a trench capacitor, or a substrate-plate capacitor. In some implementations, the capacitor dielectric includes dielectric materials, such as silicon oxide, silicon nitride, or high-k dielectrics including, but not limited to, Al2O3, HfO2, Ta2O5, ZrO2, TiO2, or any combination thereof. It is understood that in some examples, a capacitor 128 may be a ferroelectric capacitor used in a FRAM cell, and the capacitor dielectric may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

As shown in FIG. 1, vertical transistor 126 extends vertically through and contacts the word lines 134, source or drain 138 of vertical transistor 126 at the lower end thereof is in contact with the bit line 123, and source or drain 138 of vertical transistor 126 at the upper end thereof is coupled to the capacitor 128. That is, the bit line 123 and the capacitor 128 can be disposed in different planes in the vertical direction and coupled to opposite ends of vertical transistor 126 of DRAM cell 124 in the vertical direction due to the vertical arrangement of vertical transistor 126. In some implementations, the bit line 123 and the capacitor 128 are disposed on opposite sides of the vertical transistor 126 in the vertical direction, which simplifies the routing of the bit lines 123 and reduces the coupling capacitance between the bit lines 123 and the capacitors 128 compared with DRAM cells in which the bit lines and capacitors are disposed on the same side of the planar transistors.

As shown in FIG. 1, in some implementations, the vertical transistors 126 are disposed vertically between the capacitors 128 and the bonding interface 106. That is, the vertical transistors 126 can be arranged closer to the peripheral circuits 112 of the first semiconductor structure 102 and the bonding interface 106 than the capacitors 128. Since the bit lines 123 and the capacitors 128 are coupled to opposite ends of the vertical transistors 126, the bit lines 123 (as part of the interconnect layer 122) are disposed vertically between the vertical transistors 126 and the bonding interface 106 As a result, the interconnect layer 122 including bit lines 123 can be arranged close to the bonding interface 106 to reduce the interconnect routing distance and complexity.

In some implementations, the second semiconductor structure 104 further includes a substrate 148 disposed above the DRAM cells 124. The substrate 148 can be part of a carrier wafer. It is understood that in some examples, the substrate 148 may not be included in the second semiconductor structure 104.

As shown in FIG. 1, the second semiconductor structure 104 can further include a pad-out interconnect layer 150 above the substrate 148 and the DRAM cells 124. The pad-out interconnect layer 150 can include interconnects, e.g., contact pads 154, in one or more ILD layers. The pad-out interconnect layer 150 and the interconnect layer 122 can be formed on opposite sides of the DRAM cells 124. The capacitors 128 can be disposed vertically between the vertical transistors 126 and the pad-out interconnect layer 150. In some implementations, the interconnects in pad-out interconnect layer 150 can transfer electrical signals between the 3D semiconductor device 100 and outside circuits, e.g., for pad-out purposes.

In some implementations, the second semiconductor structure 104 further includes one or more contacts 152 extending through the substrate 148 and part of the pad-out interconnect layer 150 to couple the pad-out interconnect layer 150 to the DRAM cells 124 and the interconnect layer 122. As a result, the peripheral circuits 112 can be coupled to the DRAM cells 124 through the interconnect layers 116 and 122 as well as the bonding layers 120 and 118, and the peripheral circuits 112 and the DRAM cells 124 can be coupled to outside circuits through contacts 152 and pad-out interconnect layer 150. Contact pads 154 and contacts 152 can include conductive materials including, but not limited to, W, Co, Cu, Al, silicides, or any combination thereof. In one example, the contact pad 154 may include Al, and the contact 152 may include W. In some implementations, the contact 152 includes a via surrounded by a dielectric spacer (e.g., having silicon oxide) to electrically separate the via from substrate 148. Depending on the thickness of substrate 148, contact 152 can be an ILV having a depth in the submicron level (e.g., between 10 nm and 1 μm), or a TSV having a depth in the micron—or tens micron—level (e.g., between 1 μm and 100 μm).

Although not shown, it is understood that the pad-out of 3D memory devices is not limited to from the second semiconductor structure 104 having DRAM cells 124 as shown in FIG. 1 and may be from the first semiconductor structure 102 having peripheral circuit 112. Although not shown, it is also understood that the air gaps between word lines 134 and/or between semiconductor bodies 130 may be partially or fully filled with dielectrics. Although not shown, it is further understood that more than one array of DRAM cells 124 may be stacked over one another to vertically scale up the number of DRAM cells 124.

In some implementations, instead of having the substrate 148 above the DRAM cells 124 as shown in FIG. 1, the second semiconductor structure 104 includes a substrate disposed below the DRAM cells 124. The substrate can be part of a carrier wafer. The DRAM cells 124 can be formed in a front side of the substrate, and the bit lines 123 can be formed in a back side of the substrate. The bit lines 123 can be conductively coupled to the DRAM cells 124 (e.g., the terminals 138 of the vertical transistors 126) through the substrate.

FIG. 2 illustrates a cross-section view of an example connection structure 200. The connection structure 200 can be implemented as the connection structure 142 in FIG. 1. The connection structure 200 can include a first end 202 and a second end 204. The first end 202 of the connection structure 200 can be in contact with the first end 172 of the semiconductor body 130, as illustrated in FIG. 1. The second end 204 of the connection structure 200 can be coupled to the first electrode of the capacitor 128, as illustrated in FIG. 1. In some implementations, at least the first end 202 of the connection structure 200 has a seamless conductive portion 206. The seamless conductive portion 206 can include a conductive material without air gap. Air gaps can be voids that are presented in the conductive material. These voids can vary in shape and orientation. For examples, air gaps can have an elongated shape that is extended along Z direction or in a direction closely aligned with the Z direction. Absent such air gaps, the seamless conductive portion 206 can be substantially smooth and uniform.

In some implementations, the conductive material includes germanium silicon (GeSi). The GeSi can be formed by molecular beam epitaxy (MBE) and/or low-pressure chemical vapor deposition (LPCVD). In some implementations, the conductive material, e.g., GeSi, is grown epitaxially by MBE techniques. Without limiting to any particular theory, a crystalline layer of GeSi is grown on top of a silicon substrate in such a way that the crystal structure of the GeSi layer mirrors that of the substrate. Epitaxial growth can ensure that the crystal lattice of the growing layer, e.g., the GeSi layer, aligns with that of the substrate, e.g., the semiconductor body 130. This alignment can promote the seamless extension of the crystal structure during growth, and reducing air gaps in the GeSi layers. In addition, epitaxial GeSi can be deposited atom by atom or molecule by molecule, allowing for precise control over film thickness and uniformity. This deposition technique can also contribute to the formation of the seamless conductive portion 206.

In some implementations, the conductive material, e.g., GeSi, is grown by LPCVD techniques. Precursors can be utilized in the LPCVD deposition process. Precursors can include germane (GeH₄), disilane (Si₂H₆), or other germanium and silicon-containing compounds. Without limiting to any particular theory, during deposition process, atoms from the precursor gases can adsorb onto the substrate surface, e.g., the top surface 208 of the semiconductor body 130. Once adsorbed on the top surface 208 of the semiconductor body 130, the Ge and Si atoms can undergo a nucleation process, where small clusters or nuclei of GeSi atoms are formed. These nuclei can act as sites for further growth, as additional Ge and Si atoms continue to deposit onto them. Therefore, GeSi can grow from the bottom, e.g., first end 202 of the connection structures 200, to the top, e.g., the second end 204 of the connection structures 200 in a way that forms a seamless GeSi layer. In some implementations, as shown in FIG. 2, the seamless conductive portion 206 fills the entire connection structure 200.

In some implementations, the conductive material includes a N type dopant or a P type dopant. The N type dopant can include Phosphorus (P) or Arsenic (As), and the P type dopant can include Boron (B) or Gallium (Ga).

A connection structure 200 without air gaps or seams can provide several advantages. For example, seamless conductive materials can reduce the likelihood of foreign conductive material contamination through such gaps or seams during subsequent manufacturing process. Further, seamless conductive materials can also provide better electrical coupling between different components in a memory array, e.g., the coupling between the transistor 126 and the capacitor 128. When connection structures are seamless, there can be less impedance and resistance to the flow of electrical signals, resulting in improved electrical performance and reliability of the memory cells.

In some implementations, a transistor 126 is formed in a substrate. As described above in FIG. 1, the transistor 126 can include a semiconductor body 130. The semiconductor body 130 can include a first end 172 and a second end 174. Both ends can be doped with N type dopants (e.g., Phosphorus (P) or Arsenic (As)) or P type dopants (e.g., Boron (B) or Gallium (Ga)) at a desired doping level, e.g., between 1E14 and 1E16 dopant atoms per cubic centimeter. The semiconductor body 130 can be formed by a plurality of processes including, but not limited to, photolithography, dry/wet etch, thin film deposition, thermal growth, implantation, chemical mechanical polishing (CMP), and any other suitable processes.

A dielectric layer 212 can be deposited on the semiconductor body 130. The dielectric layer 212 can be made of dielectric materials including, but not limited to, silicon oxide, silicon nitride, silicon oxynitride, or any combination thereof. The dielectric layer 212 can be deposited using one or more thin film deposition processes, including, but not limited to, chemical vapor deposition (CVD), physical vapor deposition (PVD), atomic layer deposition (ALD), sputtering, or any combination thereof.

An opening 210 can be subsequently formed which extends through the dielectric layer to expose the top surface 208 of the semiconductor body 130. The formation of the opening 210 can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

The seamless conductive portion 206 can then be deposited inside the opening 210. The seamless conductive portion 206 can include a conductive material, e.g., GeSi, without air gap. GeSi can be deposited by MBE, CVD, or any other suitable deposition methods. In some implementations, as shown in FIG. 2, the conductive material fills the entire opening 210. In some implementations, the seamless conductive portion 206 is used as the source or drain terminal 138 of the transistor 126.

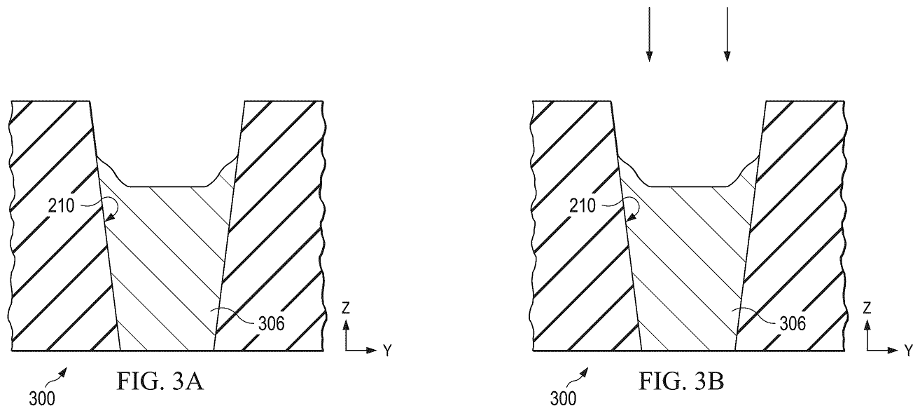

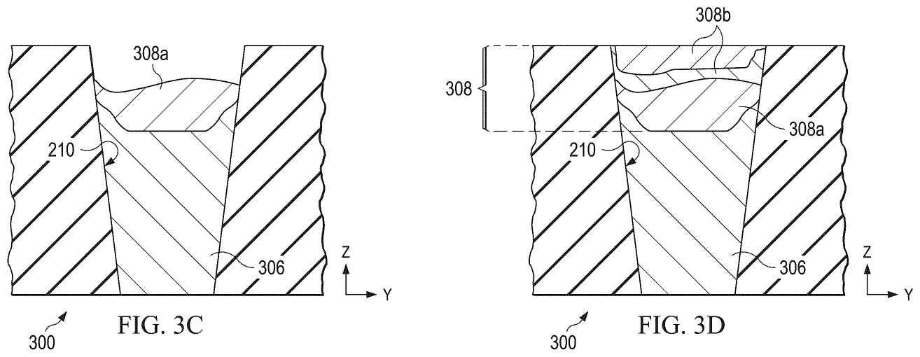

FIGS. 3A-3D illustrate cross-section views of an example connection structure 300 at various stages of a fabrication process. The connection structure 300 can be implemented as the connection structure 142 in FIG. 1. As illustrated in FIG. 3D, the connection structure 300 can include two portions, the seamless conductive portion 306 and a second conductive portion 308. The second conductive portion 308 can be above the seamless conductive portion 306 along the positive Z direction. In some implementations, the second conductive portion 308 includes a silicide material 308a having silicon (Si) and at least one of cobalt (Co), nickel (Ni) or tungsten (W). In some implementations, the silicide material 308a further includes germanium (Ge). In some implementations, the second conductive portion 308 includes a connecting layer 308b, e.g., tungsten (W) layer and a titanium nitride (TiN) layer.

Examples process steps to form the connection structure 300 are illustrated in FIGS. 3A-3C. As illustrated in FIG. 3A, the seamless conductive portion 306 can be formed inside the opening 210 utilizing process techniques as described in FIG. 2. In some implementations, the seamless conductive portion 306 includes GeSi and only partially fills the opening 210, as shown in FIG. 3A.

As illustrated in FIG. 3B, an implantation process can be performed followed by an annealing process to dope the conductive material in the seamless conductive portion 306. The dopants can be N type dopant or a P type dopant. The N type dopant can include Phosphorus (P) or Arsenic (As), and the P type dopant can include Boron (B) or Gallium (Ga). By selectively implanting dopant atoms, the electrical conductivity and carrier concentration of the conductive material can be altered. The annealing process can activate the dopants atoms and repair any damage to the crystal lattice caused during implantation.

As illustrated in FIG. 3C, the silicide material 308a can be formed above the seamless conductive portion 306 inside the opening 210. The silicide material 308a can be formed by performing a silicidation process. The silicidation process can involve depositing a conductive layer, e.g., a metal layer, on top of the seamless conductive portion 306, followed by an annealing process. During annealing, the deposited conductive layer can react with the silicon in the seamless conductive portion 306 to form a composite conductive material, e.g., the silicide material 308a. In some implementations, the silicide material 308a includes without limitation to NiSi, WSi, CoSi, CuSi, AlSi, or any other suitable metal silicides.

As illustrated in FIG. 3D, the connecting layer 308b, e.g., tungsten (W) layer and a titanium nitride (TiN) layer, can be deposited on top of the silicide material 308a along the positive Z direction. Without limiting to any particular theory, W has low resistivity and high melting pointing, providing good stability and reliability of semiconductor devices. TiN has good adhesion properties, which can help reduce the risk of delamination or peeling of layers during subsequent processing steps. The deposition of the W layer and TiN layer can utilize one or more thin film deposition techniques including, but not limited to, CVD, PVD, ALD, Metal-Organic Chemical Vapor Deposition (MOCVD), sputtering, electroplating, electroless plating, electron-beam evaporation, or any combination thereof.

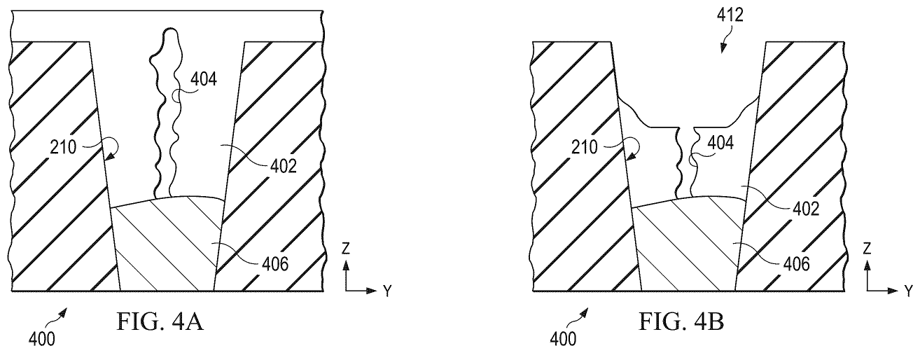

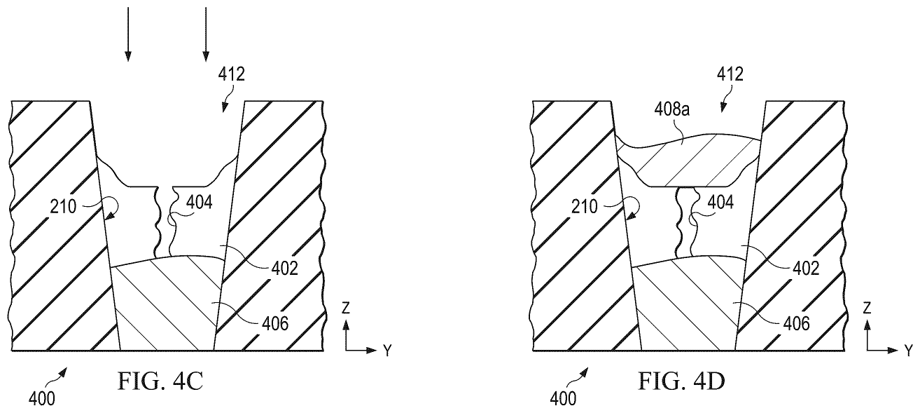

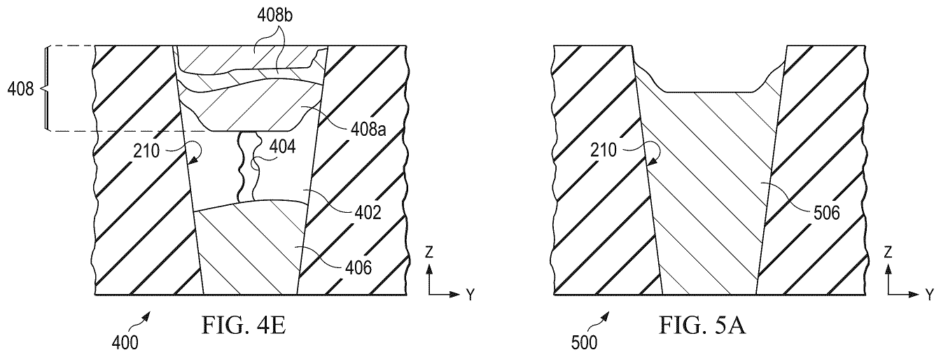

FIGS. 4A-4E illustrate cross-section views of an example connection structure 400 at various stages of a fabrication process. The connection structure 400 can be implemented as the connection structure 142 in FIG. 1. As illustrated in FIG. 4E, the connection structure 400 can include a third conductive portion 402 between the seamless conductive portion 406 and the second conductive portion 408. The seamless conductive portion 406 can include GeSi. The second conductive portion 408 can be made of a silicide material, including without limitation to NiSi, WSi, CoSi, CuSi, or AlSi. The third conductive portion 402 can include a polysilicon. The polysilicon can have an air gap 404 extending along the Z direction, as illustrated in FIG. 4E.

Examples process steps to form the connection structure 400 are illustrated in FIGS. 4A-4D. As illustrated in FIG. 4A, the third conductive portion 402 can be deposited above the seamless conductive portion 406. The third conductive portion 402 can include doped polysilicon. The polysilicon can be deposited using one or more thin film deposition processes, including, but not limited to, chemical vapor deposition (CVD), physical vapor deposition (PVD), atomic layer deposition (ALD), sputtering, or any combination thereof. In some cases, during deposition, gases can be trapped within the polysilicon due to the narrow geometry of the opening 210. These trapped gases can hinder the uniform deposition of polysilicon and create voids or air gaps 404 inside the polysilicon, as illustrated in FIG. 4A.

As illustrated in FIG. 4B, the third conductive portion 402 can be partially recessed or etched to form cavity 412 on the upper portions of the opening 210. The etching process can involve one or more dry etching and/or wet etching process, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H₂SO₄/H₂O₂), or any combination thereof.

As illustrated in FIG. 4C, an implantation process can be performed followed by an annealing process to dope the third conductive portion 402, e.g., the polysilicon. The dopants can be N type dopant or a P type dopant. The N type dopant can include Phosphorus (P) or Arsenic (As), and the P type dopant can include Boron (B) or Gallium (Ga).

As illustrated in FIG. 4D, a silicide material 408a can be formed above the third conductive portion 402, e.g., the polysilicon, inside the opening 210. The silicide material 408a can be formed by performing a silicidation process. The silicidation process can involve depositing a first conductive layer on top of the polysilicon, followed by an annealing process. During annealing, the first conductive layer can react with the polysilicon in the third conductive portion 402 to form a first composite conductive material, e.g., the silicide material 408a. In some implementations, the silicide material includes 408a without limitation to NiSi, WSi, CoSi, CuSi, AlSi, or any other suitable metal silicides.

As illustrated in FIG. 4E, a connecting layer 408b, e.g., tungsten (W) layer and a titanium nitride (TiN) layer, can be deposited on top of the silicide material 408a along the positive Z direction. The connecting layer 408b can be formed by the deposition techniques as described above in FIG. 3D.

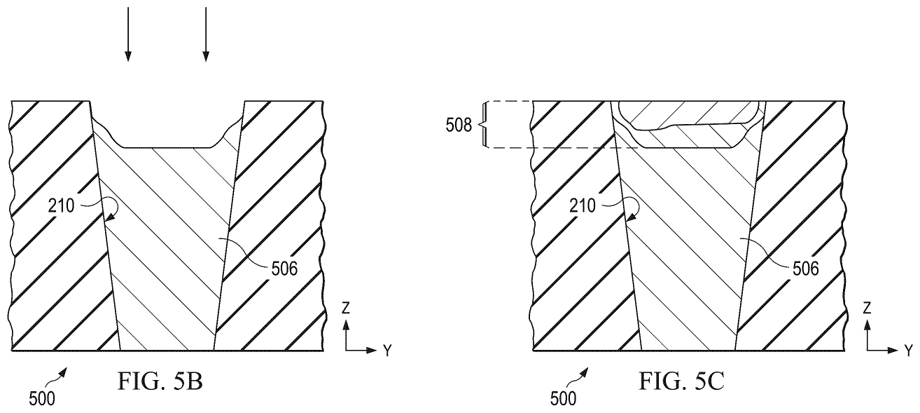

FIGS. 5A-5C illustrate cross-section views of an example connection structure 500 at various stages of a fabrication process. The connection structure 500 can be implemented as the connection structure 142 in FIG. 1. As illustrated in FIG. 5C, the connection structure 500 can include a seamless conductive portion 506 and a connecting layer 508 above the seamless conductive portion 506. As illustrated in FIGS. 5A-5B, the seamless conductive portion 506 can be formed by depositing the conductive material, e.g., GeSi, in the opening 210 followed by an implantation process. The connecting layer 508, e.g., tungsten (W) layer and a titanium nitride (TiN) layer, can be subsequently deposited on top of the seamless conductive portion 506. The process techniques for forming the connection structure 500 can be the same as or similar to those described in FIGS. 2-4E.

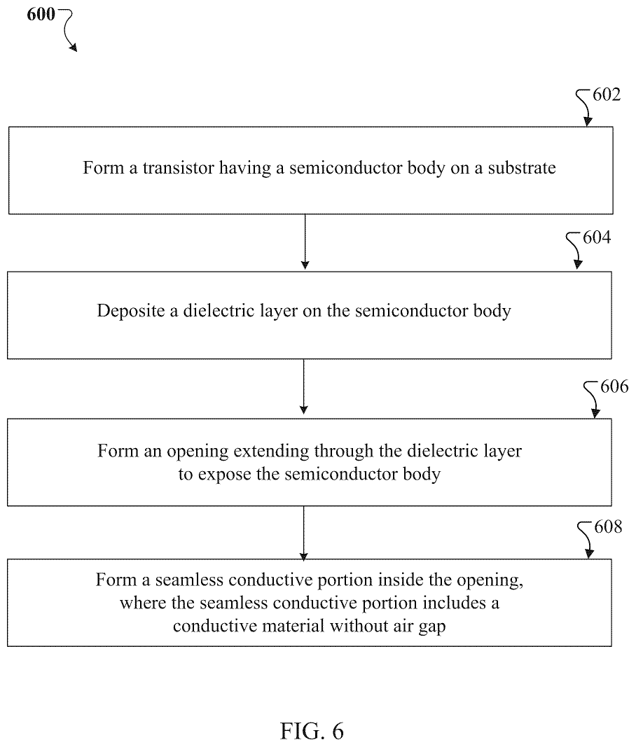

FIG. 6 illustrates an example process 600 to form an example semiconductor device.

At step 602, a transistor is formed which includes a semiconductor body on a substrate. The semiconductor body can be, e.g., the semiconductor body 130 of FIGS. 1-2. The transistor can be, e.g., the transistor 126 of FIG. 1.

At step 604, a dielectric layer is deposited on the semiconductor body. The dielectric layer can be, e.g., the dielectric layer 212 of FIGS. 2-5C.

At step 606, an opening 210 is formed which extends through the dielectric layer to expose the semiconductor body. The opening 210 can be, e.g., the opening 210 of FIGS. 2-5C.

At step 608, a seamless conductive portion is formed inside the opening 210. The seamless conductive portion includes a conductive material without air gap. The seamless conductive portion can form a connection structure or part of the connection structure. The connection structure can be, e.g., the connection structure 142 of FIG. 1, the connection structure 200 of FIG. 2, the connection structure 300 of FIGS. 3A-3D, the connection structure 400 of FIGS. 4A-4E, or the connection structure 500 of FIGS. 5A-5C. The seamless conductive portion can be, e.g., the seamless conductive portion 206 of FIG. 2, the seamless conductive portion 306 of FIGS. 3A-3D, the seamless conductive portion 406 of FIGS. 4A-4E, or the seamless conductive portion 506 of FIGS. 5A-5C. In some implementations, the conductive material includes germanium silicon (GeSi).

In some implementations, forming the seamless conductive portion inside the opening 210 includes growing the conductive material from a bottom of the opening 210 towards a top of the opening 210. In some implementations, the conductive material is grown from the bottom of the opening 210 towards the top of the opening 210 using epitaxial growth or low-pressure chemical vapor deposition (LPCVD).

In some implementations, the process 600 includes depositing polysilicon on the seamless conductive portion inside the opening 210, as illustrated in FIG. 4A.

In some implementations, the process 600 includes depositing a first conductive layer on the polysilicon and annealing the first conductive layer such that the first conductive layer reacts with the polysilicon to form a first composite conductive material, as descried above in FIG. 4D.

In some implementations, the process 600 includes depositing a conductive layer on the seamless conductive portion and annealing the conductive layer such that the conductive layer reacts with the conductive material in the seamless conductive portion to form a composite conductive material, as described above in FIG. 3C.

In some implementations, the process 600 includes depositing a titanium nitride (TiN) layer and a tungsten (W) layer on the first composite conductive material, as described above in FIGS. 3D and 4E.

In some implementations, the process 600 includes depositing a titanium nitride (TiN) layer and a tungsten (W) layer on the seamless conductive portion, as described above in FIG. 5C.

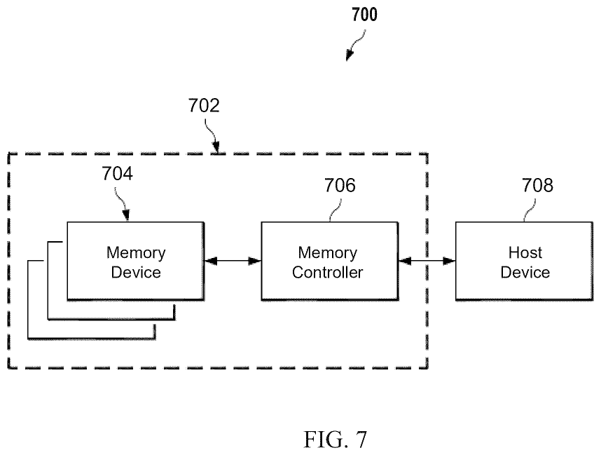

FIG. 7 illustrates a block diagram of a system 700 having one or more semiconductor devices (e.g., memory devices), according to one or more implementations of the present disclosure. The system 700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, the system 700 can include a host device 708 and a memory system 702 having one or more 3D memory devices 704 and a memory controller 706. Host device 708 can include a processor of an electronic device, such as a central processing unit (CPU), or a system-on-chip (SoC), such as an application processor (AP). Host device 708 can be configured to send or receive data to or from the one or more 3D memory devices 704.

A 3D memory device 704 can be any 3D memory device disclosed herein, such as the 3D semiconductor device 100 of FIG. 1, or a structure at an intermediate fabrication process of the 3D semiconductor device of FIGS. 2-6.

In some implementations, a 3D memory device 704 includes a NAND Flash memory. Memory controller 706 (a.k.a., a controller circuit) is coupled to 3D memory device 704 and host device 708. Consistent with implementations of the present disclosure, 3D memory device 704 can include a plurality of conductive interconnections through a cover layer that are in contact with conductive pads in a conductive pad layer, and memory controller 706 can be coupled to 3D memory device 704 through at least one of the plurality of conductive interconnections. Memory controller 706 is configured to control 3D memory device 704. For example, memory controller 706 may be configured to operate a plurality of channel structures via word lines. Memory controller 706 can manage data stored in 3D memory device 704 and communicate with host device 708.

In some implementations, memory controller 706 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 706 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 706 can be configured to control operations of 3D memory device 704, such as read, erase, and program (or write) operations. Memory controller 706 can also be configured to manage various functions with respect to the data stored or to be stored in 3D memory device 704 including, but not limited to bad-block management, garbage collection, logical-to-physical address conversion, wear leveling, etc. In some implementations, memory controller 706 is further configured to process error correction codes (ECCs) with respect to the data read from or written to 3D memory device 704. Any other suitable functions may be performed by memory controller 706 as well, for example, formatting 3D memory device 704.

Memory controller 706 can communicate with an external device (e.g., host device 708) according to a particular communication protocol. For example, memory controller 706 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 706 and one or more 3D memory devices 704 can be integrated into various types of storage devices, for example, be included in the same package, such as a universal Flash storage (UFS) package or an eMMC package. That is, memory system 702 can be implemented and packaged into different types of end electronic products. In one example as shown in FIG. 6, memory controller 706 and a single 3D memory device 704 may be integrated into a memory card 702. Memory card 702 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−0.10%, .+−0.20%, or .+−0.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a transistor comprising a semiconductor body having a first end and a second end that are doped; and
a connection structure comprising a first end and a second end, wherein the first end of the connection structure is a seamless conductive portion comprising a conductive material without air gap, and wherein the first end of the connection structure is in contact with the first end of the semiconductor body.

2. The semiconductor device of claim 1, wherein the conductive material comprises germanium silicon (GeSi).

3. The semiconductor device of claim 2, wherein the conductive material comprises a N type dopant or a P type dopant.

4. The semiconductor device of claim 1, wherein the connection structure comprises a second conductive portion on the seamless conductive portion.

5. The semiconductor device of claim 4, wherein the second conductive portion comprises a silicide material having silicon (Si) and at least one of cobalt (Co), nickel (Ni) or tungsten (W).

6. The semiconductor device of claim 5, wherein the silicide material further comprises germanium (Ge).

7. The semiconductor device of claim 4, wherein the second conductive portion comprises a tungsten (W) layer and a titanium nitride (TiN) layer.

8. The semiconductor device of claim 5, wherein the semiconductor body extends along a direction, and the connection structure comprises a third conductive portion between the seamless conductive portion and the second conductive portion, the third conductive portion comprising a polysilicon with an air gap extending along the direction.

9. The semiconductor device of claim 1, further comprising a capacitor having a first electrode, wherein the second end of the connection structure is coupled to the first electrode of the capacitor.

10. The semiconductor device of claim 1, further comprising a bit line, wherein the second end of the connection structure is coupled to the bit line.

11. A method, comprising:
forming a transistor comprising a semiconductor body on a substrate;
depositing a dielectric layer on the semiconductor body;
forming an opening extending through the dielectric layer to expose the semiconductor body; and
forming a seamless conductive portion inside the opening, wherein the seamless conductive portion comprises a conductive material without air gap.

12. The method of claim 11, wherein forming the seamless conductive portion inside the opening comprises:
growing the conductive material from a bottom of the opening towards a top of the opening.

13. The method of claim 11, wherein the conductive material comprises germanium silicon (GeSi).

14. The method of claim 12, wherein the conductive material is grown from the bottom of the opening towards the top of the opening using epitaxial growth or low-pressure chemical vapor deposition (LPCVD).

15. The method of claim 11, further comprising depositing polysilicon on the seamless conductive portion inside the opening.

16. The method of claim 15, further comprising: depositing a first conductive layer on the polysilicon and annealing the first conductive layer such that the first conductive layer reacts with the polysilicon to form a first composite conductive material.

17. The method of claim 11, further comprising: depositing a conductive layer on the seamless conductive portion and annealing the conductive layer such that the conductive layer reacts with the conductive material in the seamless conductive portion to form a composite conductive material.

18. The method of claim 16, further comprising: depositing a titanium nitride (TiN) layer and a tungsten (W) layer on the first composite conductive material.

19. The method of claim 11, further comprising: depositing a titanium nitride (TiN) layer and a tungsten (W) layer on the seamless conductive portion.

20. A system, comprising:
a memory device configured to store data, the memory device comprising:
a transistor comprising a semiconductor body having a first end and a second end that are doped, and
a connection structure comprising a first end and a second end, wherein the first end of the connection structure is a seamless conductive portion comprising a conductive material without air gap, and wherein the first end of the connection structure is in contact with the first end of the semiconductor body; and
a memory controller coupled to the memory device and configured to operate the memory device.
